(19) United States
(12) Patent Application Publication
(10) Pub. No.: US 2013/0298968 A1
(43) Pub. Date: Nov. 14, 2013

(54) SOLAR PANEL RACKING SYSTEM HAVING SEPARATE SUPPORT STRUCTURE AND COVER ASSEMBLY

(71) Applicants: Mika Brian Laitila, Peterborough (CA); Antero Samuel Laitila, Peterborough (CA); Tony Peter Laitila, Peterborough (CA)

(72) Inventors: Mika Brian Laitila, Peterborough (CA); Antero Samuel Laitila, Peterborough (CA); Tony Peter Laitila, Peterborough (CA)

(21) Appl. No.: 13/470,808

(22) Filed: May 14, 2012

(51) Int. Cl. H01L 31/048; F24J 2/52; F24J 2/46

(52) U.S. Cl. 136/251; 126/704; 211/41.1

(57) ABSTRACT

A ballasted mounting system for positioning a solar panel on a mounting surface. The system comprises a support structure and a cover assembly fastened to the support structure. The support structure has a plurality of support members for retaining the solar panel over the mounting surface at an inclined angle to the mounting surface, and as a proximal end positioned adjacent to the mounting surface and the solar panel attachable to a distal end of the support structure. The cover assembly comprises sheet material fastened to the support structure and having a first cover panel positioned between the support structure and the mounting surface and a second cover panel positioned between the proximal end and the distal end, such that the cover assembly cooperates with the solar panel when installed to form an interior.

### FIELD

The present invention relates to solar panel racking systems.

### BACKGROUND

Solar racking systems are designed to be capable of bearing the weight of the solar panels and maintain the structural integrity of the racking system in the presence of loading, due to environmental considerations such as snow and/or ice accumulation and wind loading. It is important that solar panels are properly installed in order to maximize panel operational lifespan and operational efficiency. Large flat top roofs are a preferred mounting location for racking systems, however these locations are also subject to stringent excess weight distribution rules due to existing structural limitations of the buildings (typically designed without solar panel installation in mind). Another consequence of using rooftops as mounting locations is that the rooftops are relatively exposed and therefore subject to increased wind exposure, which generates dynamic wind uplift forces on the racking systems. Other design considerations are static snow loading in northern climates. Therefore, there is a need for proper design of the racking systems to account for these additional dynamic and static forces.

One way to account for the wind uplift forces is to provide for ballast weights in order to resist any wind generated uplift forces, however the disadvantage with using ballast weights is increased excess weighting applied to the roof structure. Accordingly, there is a need to provide for proper aerodynamic design of the racking systems, in order to reduce the effect of the any generated uplift forces and therefore reduce the size and weight of ballast. This is important, as the alternative to ballasted racking systems are systems that are lagged to the roof surface. These lagged racking systems may not need ballast weights, however they offer the undesirable feature of penetrating the roof membrane which can cause potential leakage and voiding of roof warranties.

Further, there is increased awareness in the solar racking design community of manufacturing and material costs associated with the solar racking systems. Therefore, minimizing the amount of material used in racking system manufacture, as well as minimizing costly material components of the racking systems is desired.

### SUMMARY

It is an object of the present invention to provide a ballasted mounting system that obviate or mitigates at least one of the above-presented disadvantages.

A consequence of using rooftops as mounting locations for solar racking systems is that the rooftops are relatively exposed and therefore subject to increased wind exposure, which generates dynamic wind uplift forces on the racking systems. Other design considerations are static snow loading in northern climates. Therefore, there is a need for proper design of the racking systems to account for these additional dynamic and static forces. One way to account for the wind uplift forces is to provide for ballast weights in order to resist any wind generated uplift forces, however the disadvantage with using ballast weights is increased excess weighting applied to the roof structure. Contrary to the present prior art systems there is provided a ballasted mounting system for positioning a solar panel on a mounting surface. The system comprises a support structure and a cover assembly fastened to the support structure. The support structure has a plurality of support members for retaining the solar panel over the mounting surface at an inclined angle to the mounting surface, and as a proximal end positioned adjacent to the mounting surface and the solar panel attachable to a distal end of the support structure. The cover assembly comprises sheet material fastened to the support structure and having a first cover panel positioned between the support structure and the mounting surface and a second cover panel positioned between the proximal end and the distal end, such that the cover assembly cooperates with the solar panel when installed to form an interior.

An aspect provided is a ballasted mounting system for positioning a solar panel on a mounting surface, the system comprising: a support structure having a plurality of support members for retaining the solar panel over the mounting surface at an inclined angle to the mounting surface, the support structure having a proximal end positioned adjacent to the mounting surface and the solar panel attachable to a distal end of the support structure; and a cover assembly comprising sheet material fastened to the support structure by a plurality of fasteners and having a first cover panel positioned between the support structure and the mounting surface and a second cover panel positioned between the proximal end and the distal end, the cover assembly being separate from the support structure and attachable and detachable to the support structure via the plurality of fasteners.

### BRIEF DESCRIPTION OF THE DRAWINGS

Exemplary embodiments of the invention will now be described in conjunction with the following drawings, by way of example only, in which:

FIG. 1 is a front perspective view of a ballasted mounting system without solar panel;

FIG. 2 is a rear perspective view of FIG. 1 of the ballasted mounting system with solar panel;

FIG. 3 is a planar side view of a cover assembly of the ballasted mounting system of FIG. 1;

FIG. 4 is an alterative embodiment of the ballasted mounting system of FIG. 1;

FIG. 5 is a perspective view of a support member of the support structure of the ballasted mounting system of FIG. 1;

FIG. 6 is an alternative embodiment of the support member of FIG. 5;

FIG. 7 is a perspective view of the cover assembly of FIG. 1 including footings;

FIG. 8 is a side view of an alternative embodiment of the ballasted mounting system of FIG. 1;

FIG. 9 is a side view of a further alternative embodiment of the ballasted mounting system of FIG. 1;

FIG. 10 shows a perspective view of a solar array having multiple ballasted mounting systems of FIG. 1;

FIG. 11 is a side view of the ballasted mounting system of FIG. 1 with solar panel;

FIG. 12 is a front view of the ballasted mounting system of FIG. 1 with solar panel;

FIG. 13 is an alternative embodiment of the ballasted mounting system of FIG. 12 with solar panel;

FIG. 14 shows a rear perspective view of the ballasted mounting system of FIG. 1 with air gap;

FIG. 15 shows an exploded perspective view of assembly of the ballasted mounting system of FIG. 1;

FIG. 16 is a further exploded perspective view of assembly of the ballasted mounting system of FIG. 1;

FIG. 17 is a cross-sectional view of an assembled cover assembly and support structure for adjacent ballasted mounting systems of FIG. 1; and

FIG. 18 shows a perspective exploded front view of connection between the cover assembly and the support structure of the ballasted mounting system of FIG. 1.

### DESCRIPTION OF PREFERRED EMBODIMENTS

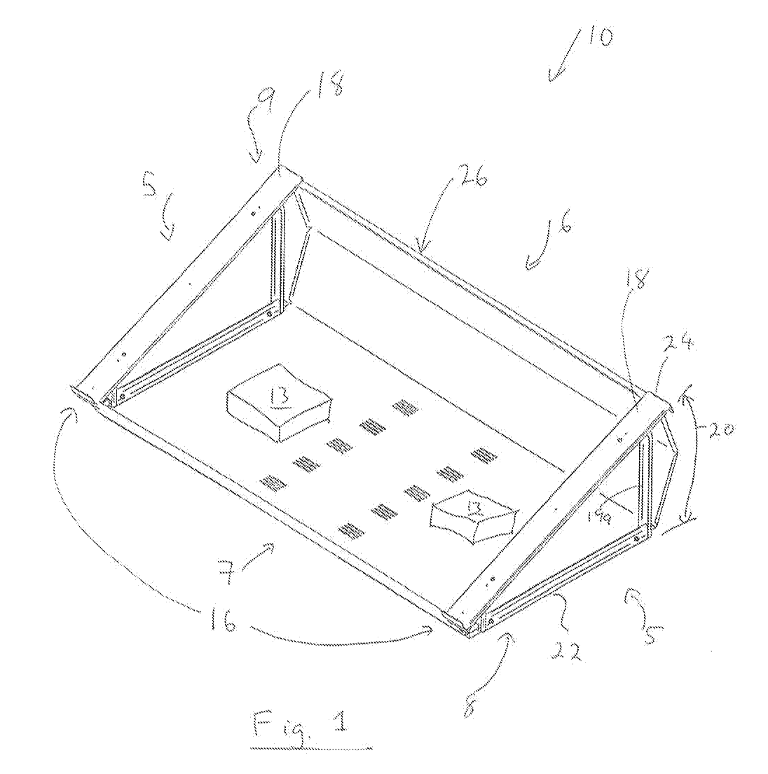

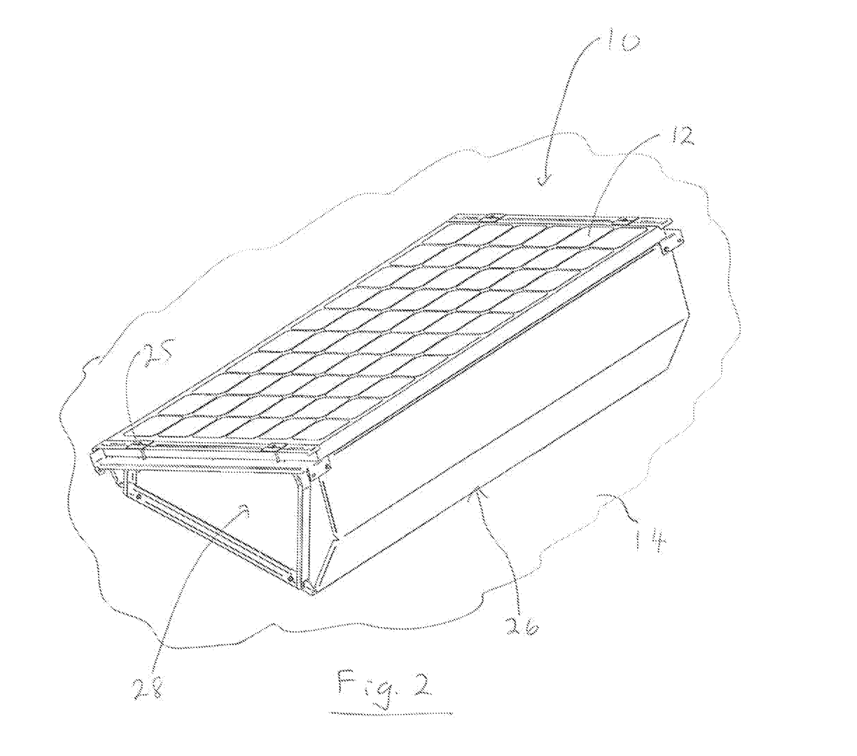

Referring to FIG. 1, shown is a ballasted mounting system 10 for supporting a solar panel 12 (e.g. photovoltaic collector, solar thermal collector, etc.) over a mounting surface 14 (see FIG. 2). The system 10 has a support structure 16 with a number of individual support members 18 for attaching to and retaining the solar panel 12 over the mounting surface 14, preferably at an inclined angle 20 to the mounting surface 14. The support structure 16 has a proximal end 22 positioned adjacent to the mounting surface 14 and a distal end 24 attachable (for example using mechanical fasteners 25 such as bolts or screws) to the solar panel 12. The system 10 has a rear side 6, a front side 7, a bottom side 8 and a top side 9, such that the bottom side 8 is positioned adjacent to the mounting surface 14 and the top side 9 is configured to receive and hold the solar panel 12. The system 10 can also have end sides 5 and accommodate the placement of ballast weights 13 in an interior 28 (see FIG. 2).

The support members 18 of the support structure 16 are designed to be capable of bearing the weight of the solar panel 12, so as to inhibit the mounting system 10 from collapsing (i.e. experience failure in the structural integrity of the mounting system 10). It is recognized that the support members 18 are also designed to maintain the structural integrity of the system 10 in the presence of loading, due to environmental considerations, such as snow and/or ice accumulation and wind loading. It is recognized that the mounting surface 14 can be a suitable surface such as but not limited to a relatively level rooftop of a building, a mildly sloped rooftop, and a relatively flat ground surface. Preferably, the mounting surface 14 is level and/or mildly sloped (sloping can be up to 5 degrees from horizontal depending upon the coefficient of friction between the cladding of the mounting surface 14 and the mounting system 10).

Referring again to FIGS. 1, 2 and 3, the system 10 also has a cover assembly 26 manufactured out of sheet material that is fastened (for example using mechanical fasteners 25 such as bolts, rivets, pop rivets, and/or screws) to the support structure 16, thereby cooperating with the solar panel 12 to define the interior 28 of the system 10. The cover assembly 26 is a separate component of the mounting system 10 from the support structure 16 component. The cover assembly 26 is fastened to the support structure 16 by a plurality of fasteners (e.g. mechanical), such that the cover assembly 26 is detachable from the support structure 16 once installed. In other words, the cover assembly 26 can be removed from the support structure 16 by unfastening the plurality fasteners used to originally attach the cover assembly 26 to the support structure 16 during installation of the mounting system 10 on the mounting surface 14. The cover assembly 26 is separate from the support structure 16 and attachable and detachable to the support structure 16 via the plurality of fasteners.

The cover assembly 26 has a number of different panels 30 that can be used to inhibit exposure of the interior 28 from undesirable environmental elements such as but not limited to the collection of precipitation (e.g. rain or snow) in the interior 28. Further, the shape and/or orientation of the panels 30 can be designed to decrease the degree of wind loading (e.g. exerted wind uplift forces) experienced by the system 10 according to aerodynamic principles. The cover assembly 26 has a first cover panel 32 positioned between the support structure 16 and the mounting surface 12 and a second cover panel 34 positioned between the proximal end 22 and the distal end 24 of the support structure 16 at the rear side 6, such that the cover assembly 26 cooperates with the solar panel 14 to form the interior 28. The cover assembly 26 can also have a third cover panel 36 positioned between the proximal end 22 and the distal end 24 of the support structure 16 at the front side 6. It is recognized that the sheet material of the cover assembly 26 can be any durable material that is resistive to excessive damage from environmental factors such as but not limited to sunlight exposure, moisture, and/or wind and wind driven projectiles. Example sheet materials for the cover assembly 26 can be materials such as but not limited to plated steel, aluminum, and/or UV resistant plastics. It is recognised that any of the cover panels 30 can be optional in terms of the cover assembly 26. For example, the second cover panel 34 and/or the third cover panel 36 can be optional elements of the cover assembly 26. In other words, the cover assembly 26 can be embodied as just the first cover panel 32 (e.g. an open front and open rear cover assembly 26), just the first cover panel 32 and the second cover panel 34 (e.g. an open front and closed rear cover assembly 26), just the first cover panel 32 and the third cover panel 36 (e.g. an open rear and closed front cover assembly 26), just the first cover panel 32 and the second cover panel 34 and the third cover panel 36 (e.g. a closed front and a closed rear cover assembly 26), or any combination thereof. It is also recognised that according to the design of the cover assembly 26, the first cover panel 32 and the second cover panel 34 and the third cover panel 36 are integrally formed with one another as part of the sheet material. Alternatively, according to the design of the cover assembly 26, the first cover panel 32 and the second cover panel 34 are integrally formed with one another as part of the sheet material (e.g. resulting in either an open front cover assembly 26 or a closed front cover assembly 26 such that the third cover panel 36 is separate sheet material fastened—e.g. using mechanical fasteners—to the sheet material forming the first cover panel 32 and the second cover panel 34). Alternatively, according to the design of the cover assembly 26, the first cover panel 32 and the third cover panel 36 are integrally formed with one another as part of the sheet material (e.g. resulting in either an open rear cover assembly 26 or a closed front cover assembly 26 such that the second cover panel 34 is separate sheet material fastened—e.g. using mechanical fasteners—to the sheet material forming the first cover panel 32 and the third cover panel 36).

Another related consideration is that the same cover assembly 26 can be used for both northern and southern climates that encounter similar wind loading, while the support structure 16 for the northern climate installation would be rated for higher static loading due to snow load considerations as compared to the support structure 16 for the southern climate installation that would not have to account for snow loading. Thus in this example, the southern climate installation of the mounting system 10 could be lighter in system weight (as compared to the northern climate installation) as the support structure 16 for the southern climate mounting system 10 could be made out of thinner (or lower number of) materials, thus providing for cost savings due to less material usage in the construction of support structure 16.

Another reason for having separate cover assembly 26 and support structure 16 components of the mounting system 10 is that in southern climates, similar support structures 16 can be used with alternative cover assemblies 26, the difference between the different cover assemblies 26 being that a lesser number of cover panels 30 can be employed in southern climates. For example, the cover assembly 26 in southern climates can have the front cover panel 36 missing or otherwise omitted from the cover assembly 26, due to lower angles of inclination of the solar panel 12 (i.e. from the mounting surface 14) providing for a reduced need for wind deflection. For further example, the cover assembly 26 in southern climates can have the rear cover panel 34 missing or otherwise omitted from the cover assembly 26, due to lower angles of inclination of the solar panel 12 (i.e. from the mounting surface 14) providing for a reduced need for wind deflection. For further example, the cover assembly 26 in southern climates can have both the front cover panel 36 and rear cover panel 34 missing or otherwise omitted from the cover assembly 26, due to lower angles of inclination of the solar panel 12 (i.e. from the mounting surface 14) providing for a reduced need for wind deflection.

It is important that solar panels 12 are properly installed in order to maximize panel operational lifespan and operational efficiency. Large flat top roofs are a preferred mounting surface 16 for solar panels 12, however these locations are also subject to stringent excess weight (of the solar panels 12) distribution rules due to existing structural limitations of the buildings (typically designed without solar panel installation in mind). Another consequence of using rooftops as mounting surfaces 16 is that the rooftops are relatively exposed and therefore subject to increased wind exposure (e.g. generating dynamic wind uplift forces on the systems 10) as well as static snow load considerations in northern climates, thus increasing the need for proper design of the systems 10 to account for these additional dynamic and static forces exerted on the systems 10. One way to account for the wind uplift forces is to provide for ballast weights 13 (see FIG. 1) in order to resist any wind generated uplift forces, however the disadvantage with using ballast weights 13 is increased excess weighting applied to the roof structure. Accordingly, the need to provide for proper aerodynamic design of the systems 10, in order to reduce the effect of the any generated uplift forces, is desired using an optimally shaped and sized cover assembly 26.

Accordingly, it is recognized that the system 10 has main components of the support structure 16 and a separate cover assembly 26 fastened via a plurality of fasteners to the support structure 16, such that the cover assembly 26 is detachable from the support structure 16 once assembled. One advantage of having the system 10 with separate support structure 16 and cover assembly 26 components, which are assembled together using a number of different material elements (e.g. are not formed from a single piece of material such as a single piece of sheet material), is that each component can be optimized for its intended purpose, i.e. structural integrity provided by the support structure 16 in resisting environmental forces (e.g. static snow weight and dynamic wind load forces) and solar panel 12 forces (e.g. static panel weight) and wind deflection provided by the cover assembly 26 to decrease the degree of dynamic wind forces experienced by the support structure 16.

It is also recognised that since the support structure 16 and cover assembly 26 are individual and separate components of the mounting system 10, such that the support structure 16 and cover assembly 26 are manufactured out of materials that are physically separate from one another, the support structure 16 and cover assembly 26 can be preferably assembled as well as disassembled from one another using the plurality of fasteners. Thus it is advantageous in this described configuration as separate (or separable) components that the support structure 16 and cover assembly 26 can be modified or changed individually on site during installation based on environmental site considerations. For example, a support structure 16 designed for a type of solar panel 12 can be fitted with a high wind configuration of cover assembly 26 (e.g. having both second 32 and third 34 cover panels attached to the first cover panel 32), as compared to using the same support structure 16 for the same type of solar panel 12 fitted with a different cover assembly 26 for lower wind environments (e.g. having only the second 32 cover panel attached to the first cover panel 32). In this manner, the separate support structure 16 and cover assembly components of the mounting system 10 can be optimized for their intended purpose as they are attachable and detachable to one another using a plurality of fasteners. It is also recognised that since the cover assembly 26 and support structure 16 are separate components fastened to one another, they can be made out of different materials, e.g. plated steel for the support structure 16 and aluminum for the cover assembly 26, a different gauge of material for the support structure 16 as compared to the gauge of material for the cover assembly 26 (e.g. thinner sheet material for the cover assembly 26 as compared to thicker structural tubing, thicker sheet material or thicker bar stock of the support structure 16, plastic of other polymer for the cover assembly 26 as compared to metal for the support structure 16, plastic of other polymer for the support structure 16 as compared to metal for the cover assembly 26, and/or any combination thereof.

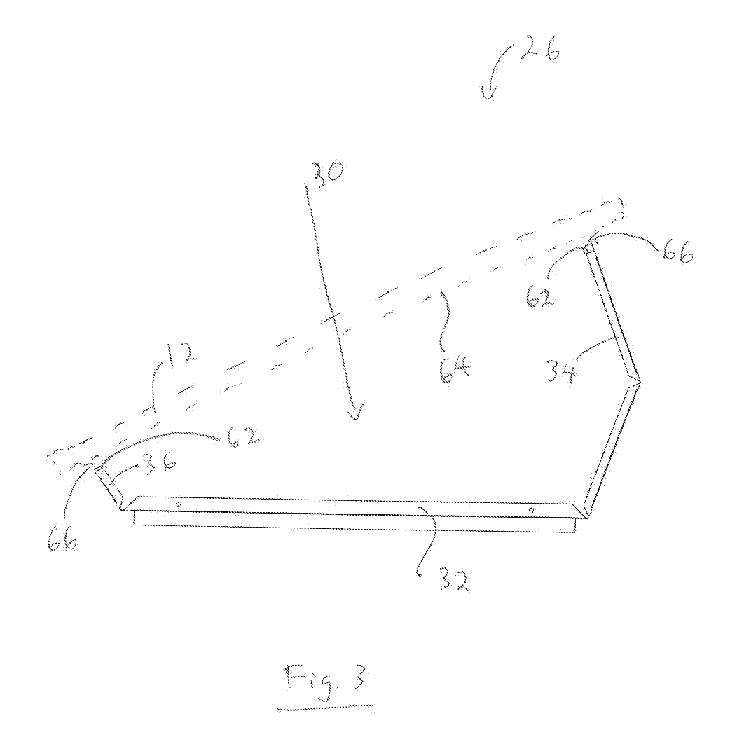

In this manner the thickness and/or type (and therefore cost) of the sheet material of the cover assembly 26 can be minimized, as the sheet material does not need to be sized (e.g. material thickness) for maintaining the structural integrity for supporting the weight of the solar panel 12 of the system 10, rather only to provide for wind deflection. As compared to the support structure 16, which needs to be configured out of material that is capable of supporting the weight of the solar panel 12 as well as environmental stresses and loads introduced to the mounting system 10 due to wind loading and/or snow loading considerations. In addition, the shape and position of the panels 30 can be optimized for wind deflection without having to also design them for their structural stability, for example the panels 30 can be positioned at angles to the solar panel 12 and mounting surface 14 that are preferential for wind deflection but are not preferential to load transfer of the solar panel 12 weight to the mounting surface 14. For example, referring to FIG. 3, the cover panel 34 is in a bent configuration due to wind deflection design optimization considerations while support element 19a of the support member 18 (see FIG. 1) is a straight element positioned parallel to the direction of the panel weight (e.g. a load transfer path parallel to gravity) assuming a relatively level mounting surface 14. Further, the material used to manufacture the support structure 16 can be comprised of less environmentally durable material due its reduced environmental exposure (i.e. due to increased protection afforded by the cover assembly 26 as compared to uncovered).

In these manners, the cost of the support structure 16 can be minimized, as optimum shape, orientation, and materials of the individual support elements 18 can be chosen without having to account for increased environmental exposure and wind deflection considerations. Further, it is recognized that for custom installations of the system 10 (e.g. degree of wind exposure, angle of wind exposure, weight of solar panels 12 and associated equipment, number of solar panels, slope angle of mounting surface 14, etc.) the separate (i.e. attachable and detachable) components of the support structure 16 and the cover assembly 26 can optimized individually for material type selection, shape and orientation design, and/or material thickness considerations, depending on whether their design purpose is structural integrity or wind deflection/environmental protection respectively.

Another consideration for having separate cover assembly 26 and support structure 16 components is for operational temperature considerations of the solar panels 12. It is recognized that use of thicker gauge sheet metal for known enclosed solar racking systems (for example U.S. Pat. No. 6,968,654 having a frame made out of sheet metal bending operations), in order to provide the required structural support to the wind, snow, and panel loading, can contribute to higher insulating R values of the known enclosed solar racking system. This can be detrimental to solar panel 12 operation, as tests show that solar panels 12 operate more efficiently at cooler temperatures. Therefore, manufacturing of solar racking systems using lower gauge sheet metal can result in decreased efficiency of panel operation and/or increased manufacturing costs due to the need to manufacture additional venting in the sheet metal.

### Support Structure 16

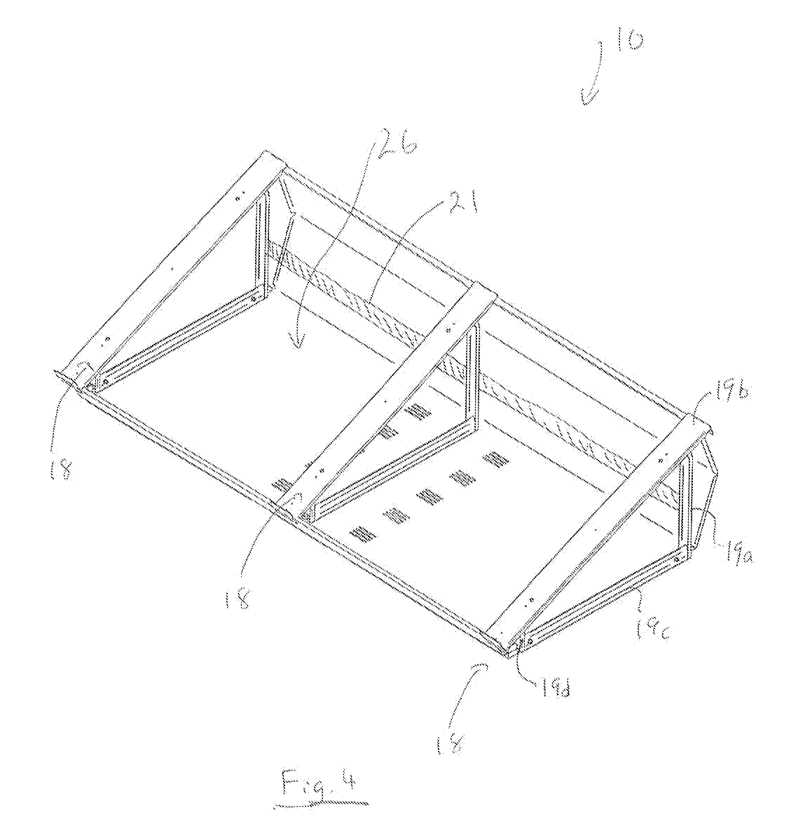

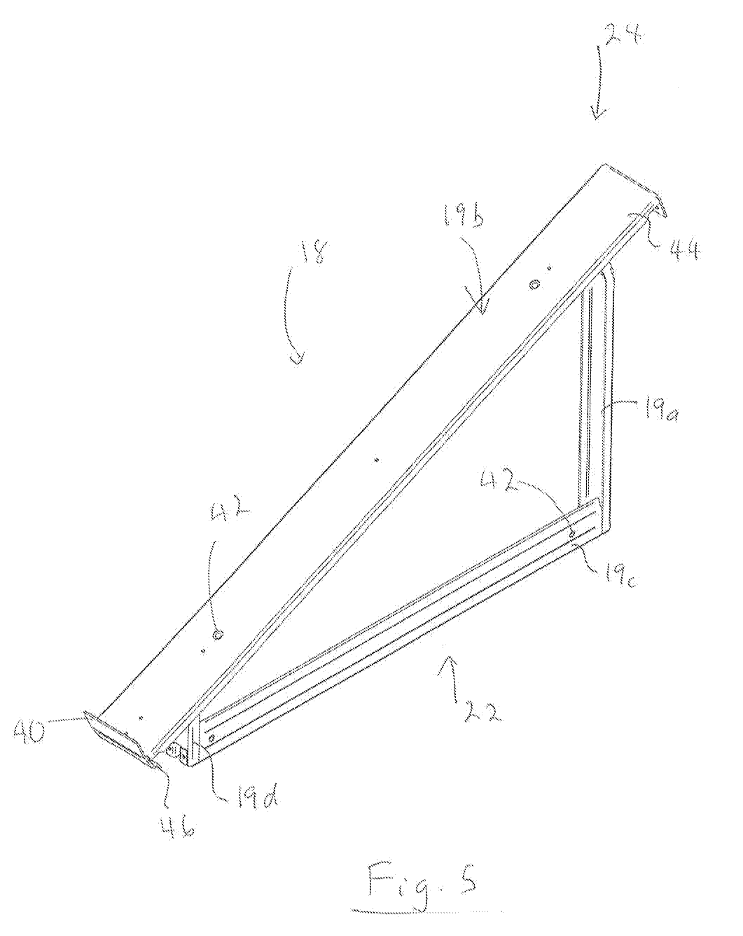

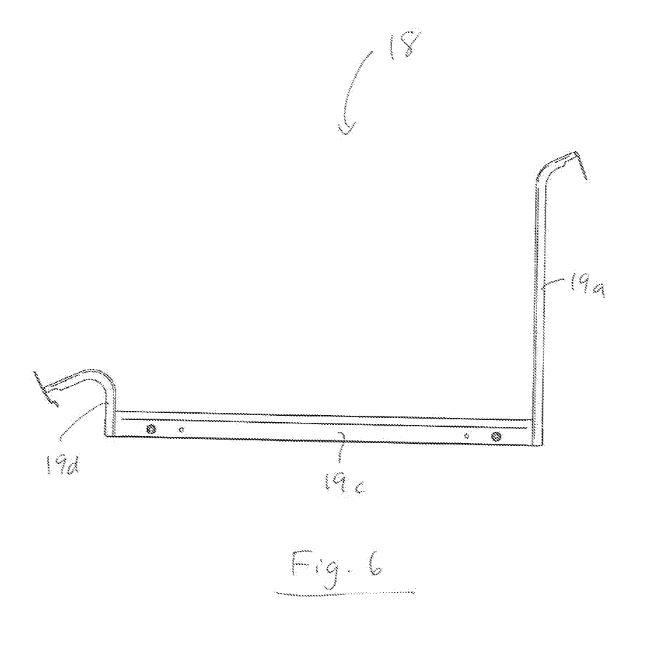

Referring to FIG. 4, it is envisioned that the support structure 16 has a number of support members 18, connected to each other directly via optional intermediate support elements 21, indirectly connected to one another through attachment to the solar panel 12 to top elements 19b, indirectly through attachment to the cover assembly 26 with bottom elements 19c, and/or a combination thereof. It is also recognized that any portion of the support members 18 can be fastened to any portion of the cover assembly 26, such as show by example by the connection of bottom cover panel 32 with member element 19c and/or the connection of the rear cover panel 34 with member element 19b and/or the connection of the front cover panel 36 with member element 19d. Further, it is recognized that the connection between the support structure 16 and the cover assembly 26 can be done preferably through mechanical fasteners 25, however alternative methods of assembly can be employed including metallurgical fastening (e.g. welding) and/or chemical fastening (e.g. adhesives). The elements 19a,b,c,d, 21 are shown by example as elongate member elements. It is also recognized that the support structure 16 can have any number of support members 18 (e.g. two are shown in FIG. 1 and three are shown in FIG. 4 by example), so long as the overall support structure 16 is capable of maintaining the structural integrity of the system 10 due to solar panel 12 loading, wind loading and any other design considerations such as snow loading. Accordingly, the support member 18 can be configured as a triangular shaped support member shown in FIG. 5, as a U shaped support member as shown in FIG. 6, or as any other shaped member so long as the support member 16 is configured to retain and support the solar panel 12 in its inclined position on the mounting surface 14.

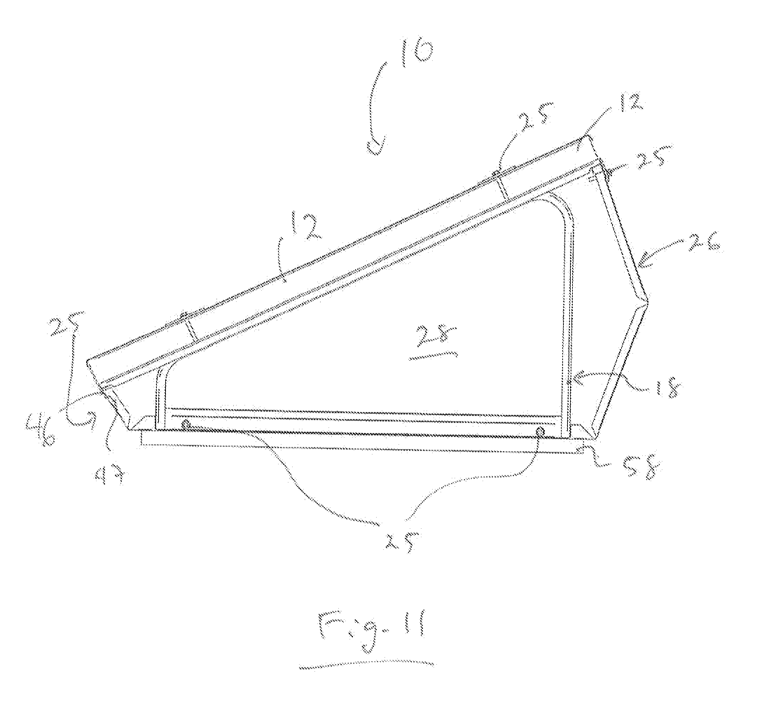

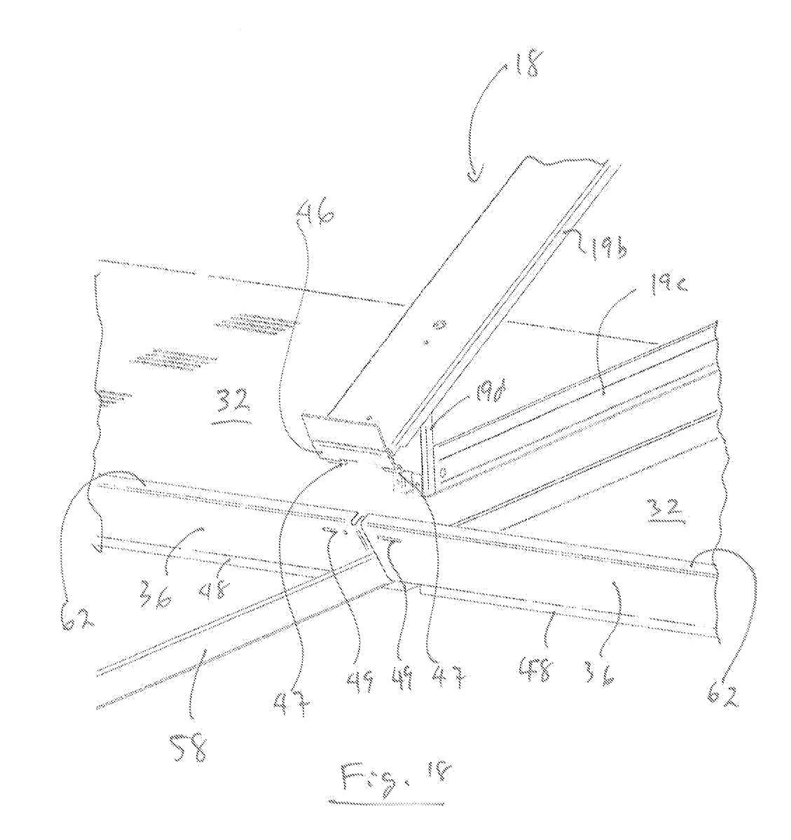

Referring to FIGS. 2 and 5, an example configuration of the support member 18 is shown having the top element 19b with support flange 40 for inhibiting the solar panel 12 from sliding off of the support member 18 and holes 42 for use with fasteners 25 that can be used to fasten the solar panel 12 to the support structure 16. The top element 19b also has a support surface 44 for receiving the underside of the solar panel 12 and can have an offset flange 46 for clipping or otherwise fastening to the cover panel 36 (see FIG. 3). Referring to FIG. 11, shown is an assembled system 10 such that connection between the offset flange 46 and the front cover panel 36 is accomplished by inserting a tab 47 of the offset flange 46 into a corresponding slot 49 (see FIG. 18) of the front cover panel 36 and then positioning the support member 18 for fastening to the cover assembly using corresponding holes and fasteners 25. The use of the offset flange 46 can reduce the need for extra fasteners 25 in connecting the cover assembly 26 and support structure 16. It is recognised that the tab 47 and slot 49 connection is considered one of the plurality of fastener mechanisms used to connect or otherwise fasten the support structure 16 to the cover assembly 26. It is also recognizable that the slot 49 could be on the offset flange 46 and the tab 49 could be on the cover panel 30, as desired.

The rear element 19a is connected to the top element 19b at the distal end 24 and to the bottom element 19c at the proximal end 22 of the support structure 16, such that the rear element 19b is positioned approximately perpendicular in orientation to the bottom element 19c, suitable for relatively level mounting surfaces 14. The front element 19d is connected to the top element 19b at the distal end 24 and to the bottom element 19c at the proximal end 22 of the support structure 16, such that the front element 19d is positioned approximately perpendicular in orientation to the bottom element 19c, suitable for relatively level mounting surfaces 14.

The bottom element 19c also has holes 24 for use with fasteners 25 for coupling the support member 18 to the cover panel 32 of the cover assembly 26, thus providing for the connection between the support structure 16 and cover assembly 26 components of the system 10. It is recognized that the support elements 19a,b,c,d can be other than as shown, including element configuration such as but not limited to bar stock, tube stock, stamped sheet stock, or a combination thereof. It is also recognized that the support member 18 can have any number of support elements 19a,b,c,d other than the four elements shown in FIG. 5. For example, referring to FIG. 6 is shown a support member 18 having only the bottom element 19c and modified front element 19d and rear element 19a, thereby relying upon the solar panel 12 (once connected) to contribute to the structural stability of the support member 18. It is also recognized that the angles between the elements 19a,b,c,d can be other than shown and that the support member 18 can be made of a support element of a unitary stamped sheet metal design (not shown).

### Cover Assembly 26

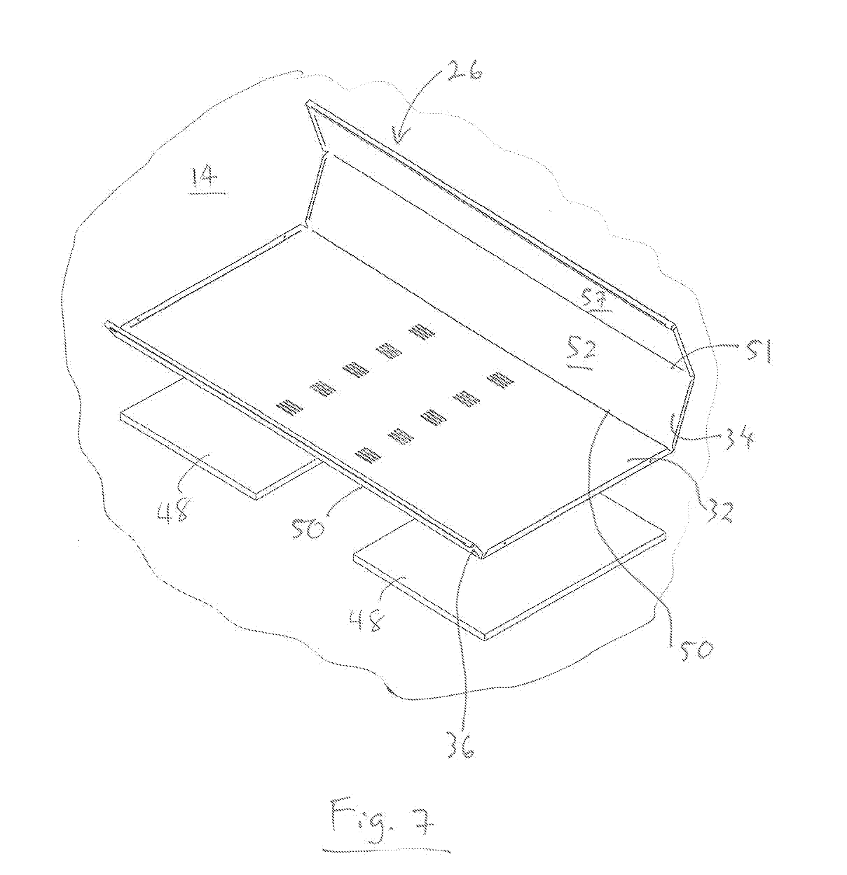

Referring to FIGS. 3 and 7, the cover assembly 26 can have any number of cover panels 30 as desired. As shown by example, the cover assembly 26 has the bottom panel 32 that has a plurality of holes (e.g. slots) therein to accommodate for drainage of any water that has penetrated into the interior 28. The rear cover panel 34 is of a V-shaped configuration for wind deflection considerations and is positioned at a non-perpendicular angle with respect to the bottom cover panel 32, however is it recognised that the second cover 34 panel can also be of arcuate design (e.g. U-shaped). The front cover panel 36 is of a shorter length than the length of the rear cover panel 34 to account for the inclined angle 20 of the solar panel 12 with respect to the mounting surface 14 (see FIG. 1). The front cover panel 36 can be straight and positioned at a non-perpendicular angle with respect to the bottom cover panel 32 for wind deflection considerations. It is also recognised that in order to minimize point loads on the mounting surface 14, delivered via the mounting system 10, is the presence of the bottom cover panel 32 in the cover assembly 26 that provides for distribution of the loads (of the support structure 16, solar panel 12, snow loading and/or wind loading) of the mounting system 10 preferably uniformly across a maximized surface area. It is also recognised that the footings 48 can be used to assist in distribution of the loading onto the mounting surface 14. It is also recognised that the larger surface area of the bottom cover panel 32 provides for a greater surface area of the footings 48 to be used, which is advantageous as it can provide for greater friction forces (e.g. through a larger coefficient of friction and/or surface area) between the mounting system 10 and the mounting surface 14. It is recognised that greater friction forces are beneficial to the mounting system 10 since they help in resisting undesirable displacement of the mounting system 10 across the mounting surface 14 due to exerted wind forces.

In terms of the connections between the cover panels 30, shown by example is the cover assembly 26 manufactured out of a single piece of sheet material with fold lines 50 to delineate between the different cover panels 30 and fold line 51 used to form the individual angled surfaces 52 of the V-shaped rear cover panel 34. However, it is also recognized that the cover panels 30 could be individual sheets that are joined together using metallurgical (e.g. welding), chemical (e.g. adhesive), and/or mechanical fastening (e.g. screws, rivets, bolts, etc.) means, as desired.

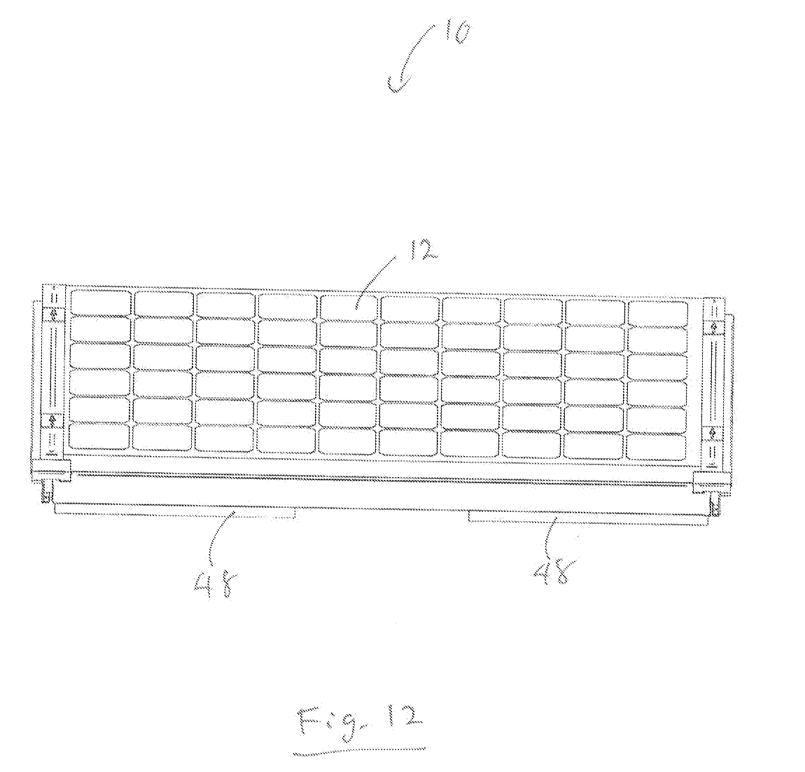

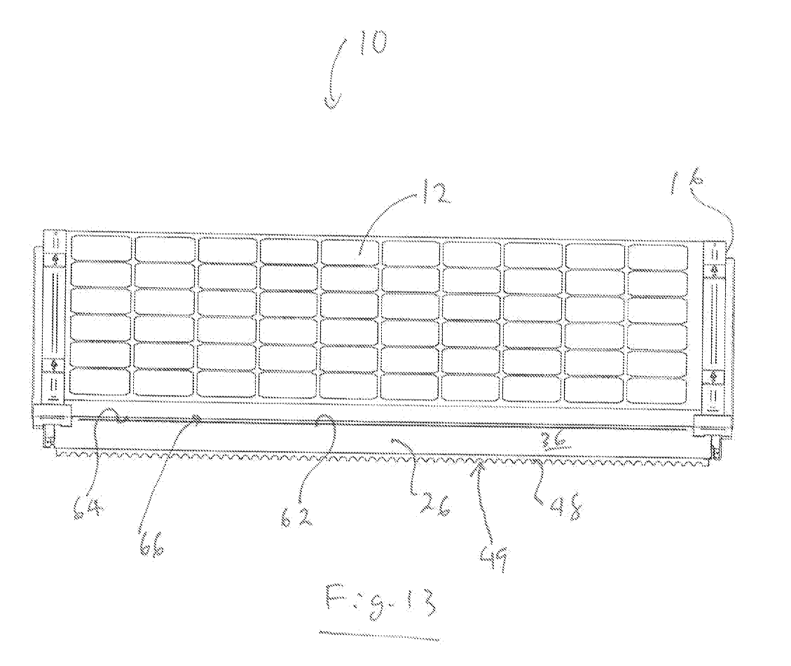

Also, footings 48 (for example made of resilient material such as but not limited to rubber, plastic, foam or other resilient polymer material that can be considered a high compression strength material such as XPS foam insulation of density 25 lbs/in2) can be positioned between the cover assembly 26 and the mounting surface 14 to help minimize point loading on the mounting surface 14 as well as to provide for adequate water drainage. FIG. 12 shows a partial footing 48 configuration providing for a space positioned between the footings 48 to provide for water drainage flow from the front to the rear of the system 10 once installed. Referring to FIG. 13, shown is an alternative embodiment of the footings 48 as a full footing that includes channels or slots 49 (also referred to as dimples) to facilitate water flow underneath the system 10 once installed on the mounting surface 14. It is also recognized that use of a full footing can provide for increased distribution of weight (e.g. a reduction in point loading) over the partial footing 48 design of FIG. 7. It is recognized that the footings 48 could be adhered or otherwise fastened to the bottom surface of the bottom cover panel 32 in order to facilitate the spreading of ballast loads (not shown) over a greater surface area of the mounting surface 14. It is recognized that provision of the footings 48 is preferred with the system 10, as the bottom cover panel 32 is preferably made of thinner gauge sheet material (as discussed above with reference to the cover panels 30 as a whole) and therefore the ability for the bottom cover panel 32 to spread ballast loads could be diminished in absence of the footings 48. As discussed above, the advantage of having separate components of the support structure 16 and the cover assembly 26 is that lower usage of material savings can be realized for the cover assembly 26, as the cover assembly 26 does not need to support the solar panel 12 in its installed position, as the retaining of the solar panel 12 in its installed position is the role or function of the support structure 16. In other words, the gauge of material for the cover assembly 26 can be minimized in order to save on cost of material for the overall mounting system 10. The preferred material in the solar racking marketplace is aluminum, which is a very expensive material so using a non-supporting cover assembly 26 provides for the use of thinner gauge aluminum in the claimed mounting system 10 over other racking systems known in the art that use their covers as cover structures to help support their solar panels. Prior art such as U.S. Pat. No. 6,968,654 or DE 20120983 uses their cover structure as their support for the solar panel, so they can't realistically use thinner gauge materials for cover manufacture. Therefore, the current mounting system 10 can offer a significant cost advantage since it is recognised that the cover can use most of the material for the mounting system 10 and can contribute most of the cost to the product. An alternative material, stainless steel, has the same cost issue.

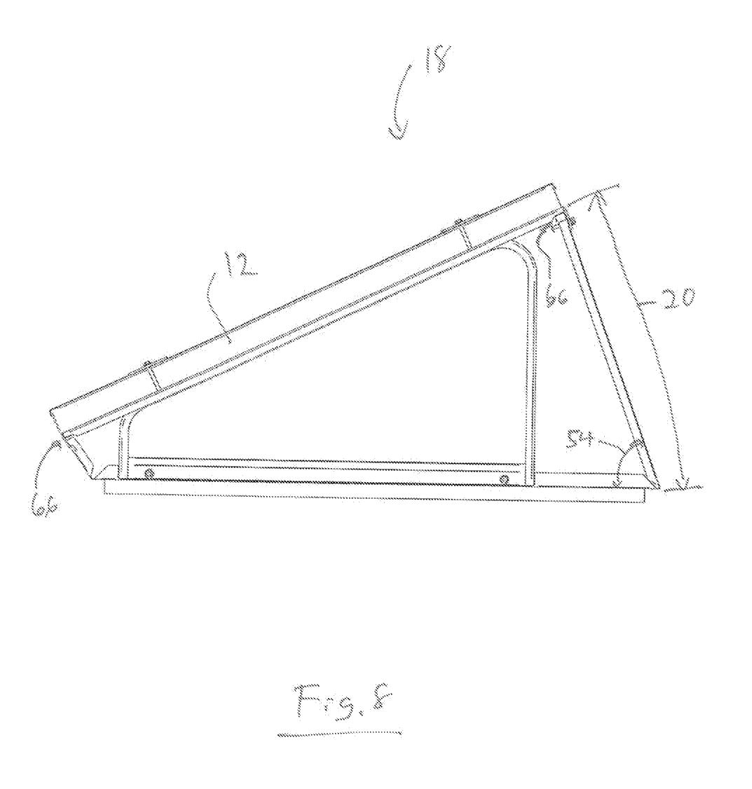

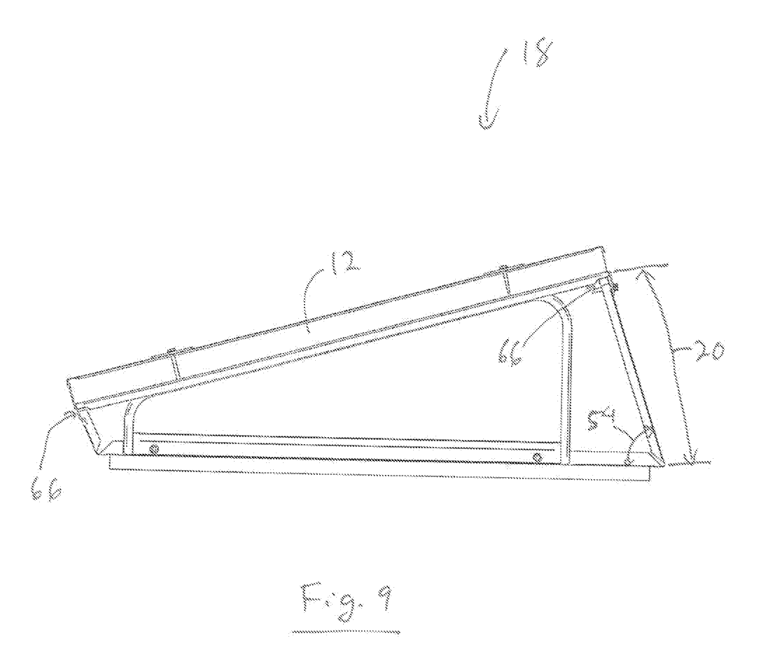

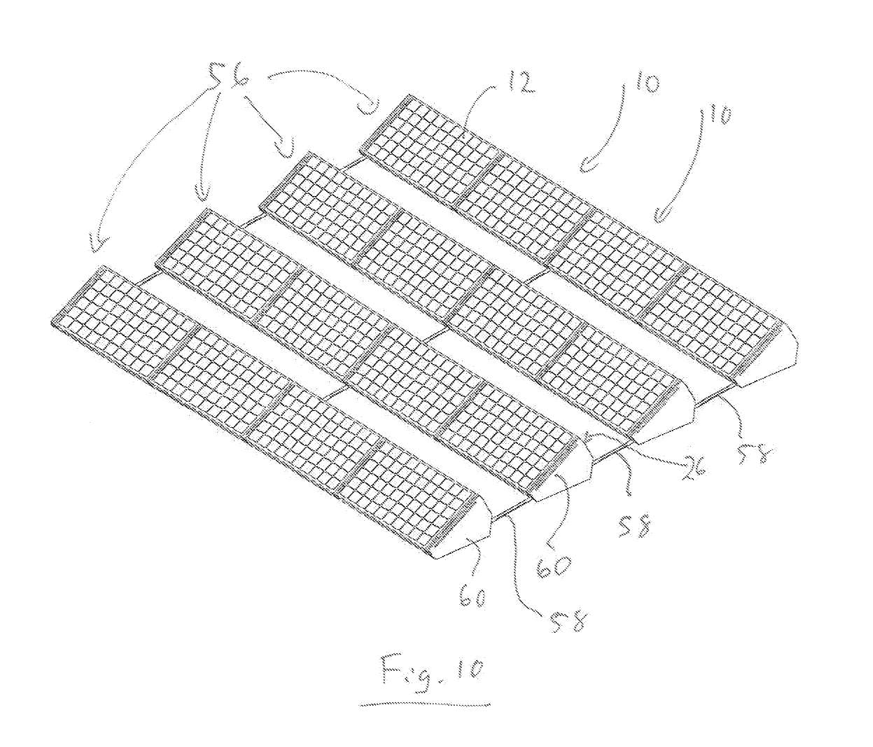

Referring to FIGS. 8 and 9, shown are alternative configurations of the cover assembly 26 for different inclination angles 20 and different non-perpendicular manufacture angles 54 to preferably account for variance in wind deflection considerations, as it is recognized that the rear cover panel 34 is preferably at the non-perpendicular angle 54 (e.g. an acute angle) with respect to the bottom cover panel 32 so that the rear cover panel 34 is configured as an angled back in order to help minimize the effect of wind loading on the system 10. Referring to FIG. 10, shown is an array of installed systems 10 in rows 56 interconnected by runners 58 used to interconnect the rows 56. Also shown is optional end cover panels 60 that are made of sheet material and considered as part of the cover assembly 26. It is recognized that the end cover panels 60 can be added to the ends of each row (e.g. two end cover panels 60 per row).

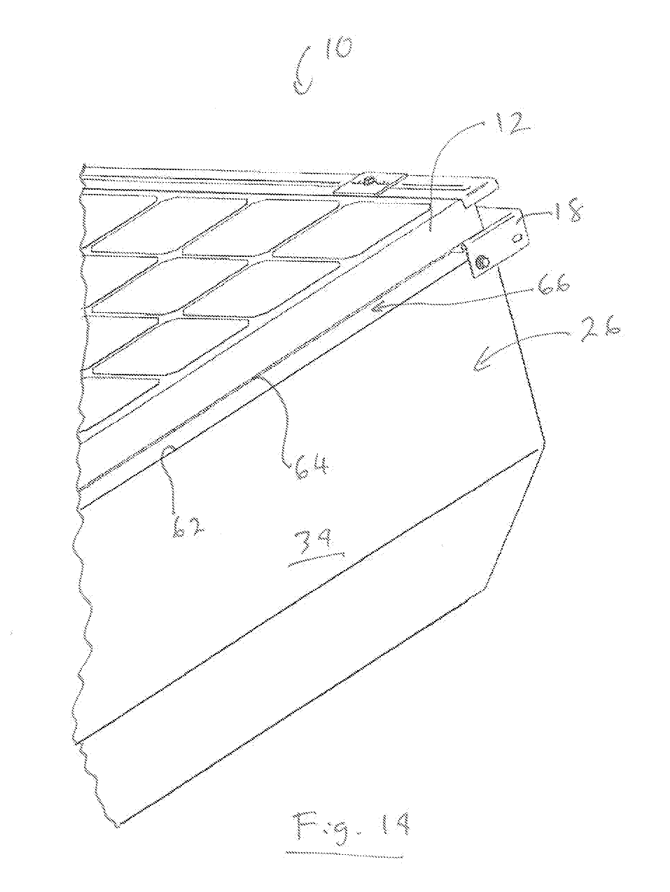

Referring to FIGS. 13 and 14, shown is the assembled system 10, such that a proximal edge 62 of the cover assembly 26 (see rear cover panel 34 and/or front cover panel 36 as an example) is spaced apart from a bottom surface 64 of the solar panel 12 (once installed on the support member 18), resulting in an air gap 66 between the cover panel 34, 36 and the solar panel 12. Preferably the air gap 66 is present with respect to both the rear cover panel 34 and the front cover panel 36 in order to promote a cross flow of air between the rear cover panel 34 and the front cover panel 36 to provide for convective cooling of the interior 28 of the system 10. It is recognized that it is advantageous (for economic reasons related to manufacturing costs) to configure the length of the panels 34,36 to be shorter than the equivalent measured distance (e.g. either a straight-line distance in the case of the example front cover panel 36 of FIG. 7 or a V-shaped distance in the case of the example rear cover panel 34) between the bottom surface 64 of the solar panel 12 and the top surface of the bottom cover panel 32. Alternatively, in the absence of forward and rearward air gaps 66, convective cooling venting (not shown) would have to be machined into one or more cover panels 30 of the cover assembly 26, thus resulting in undesirably increased manufacturing costs of the cover assembly 26. In this manner, it is recognised that the panel(s) 30 of the cover assembly 26 is/are spaced away (e.g. via air gap 66) from the bottom surface of the solar panel 12 and thus the cover panel assembly 26 is non-supporting of the solar panel 12. Instead, as discussed above the separate (i.e. attachable and detachable) components of the mounting system 10, being the cover assembly 26 and the support structure 16, perform their individual and separate functions of coverage of the mounting system 10 (e.g. for aerodynamic and/or debris collection considerations) and solar panel 12 support respectively.

### Solar Panel 12 Array Assembly

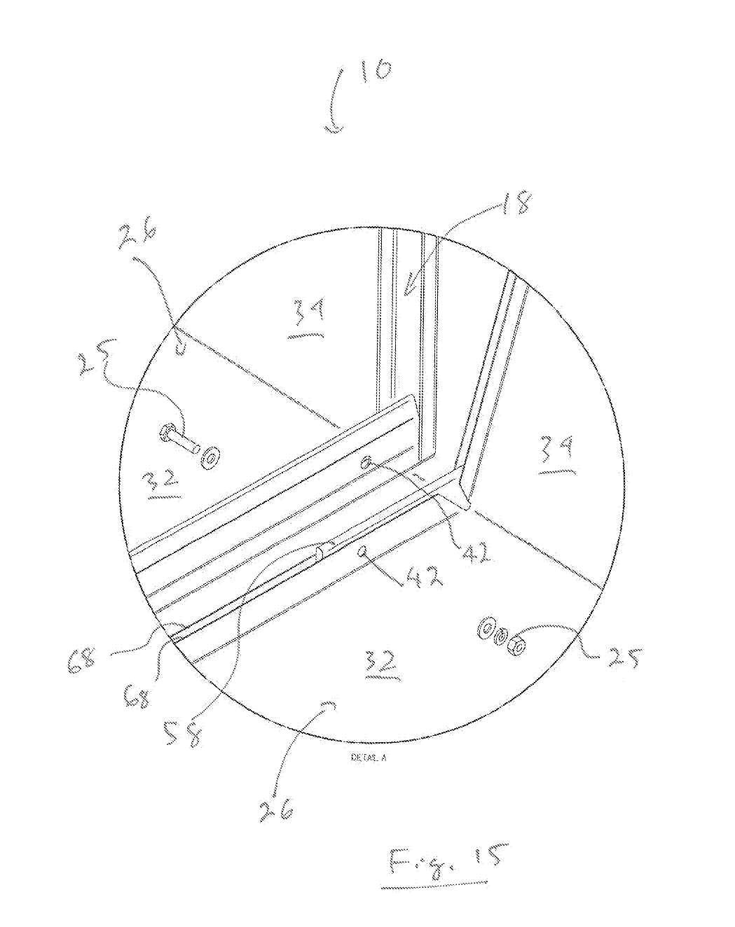

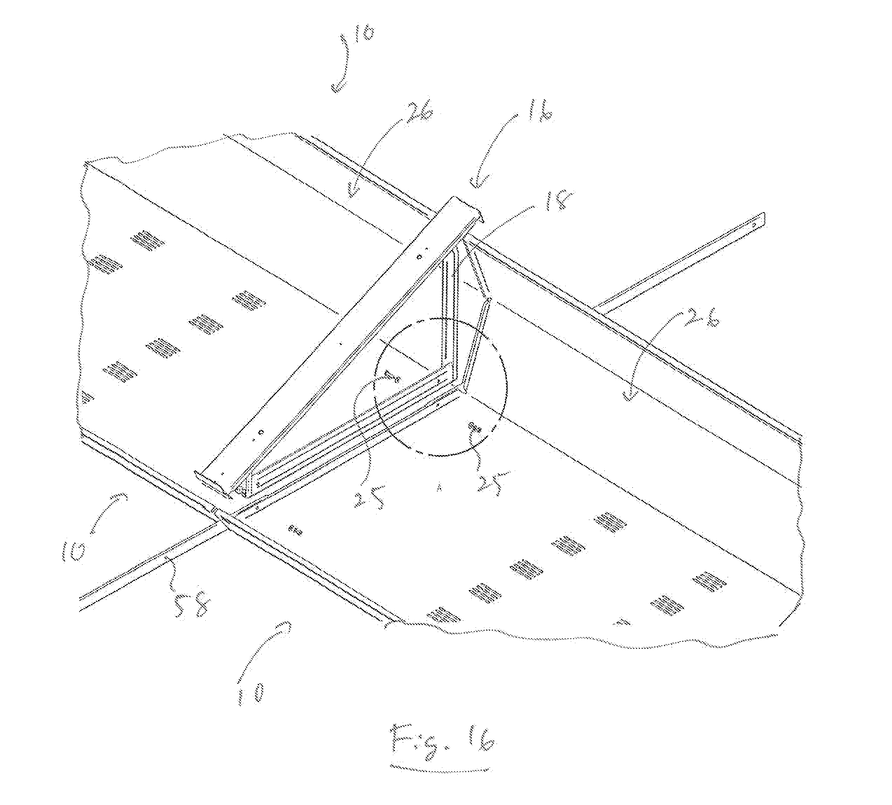

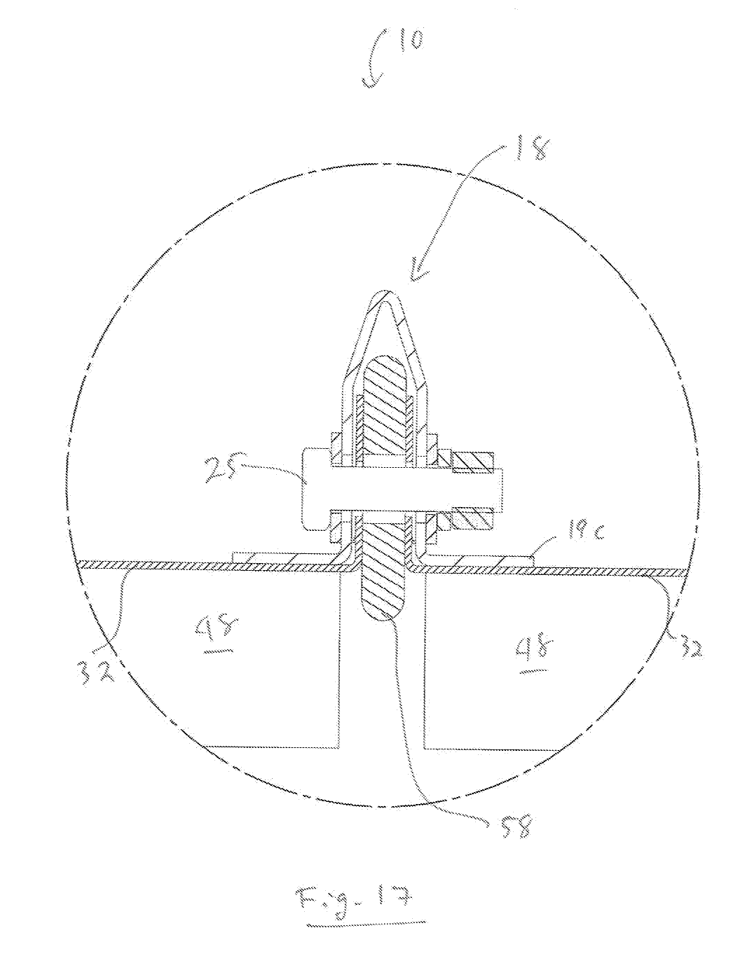

Referring to FIG. 10, as discussed above, the system 10 can be configured into a series of systems 10 in ordered rows 56, in order to accommodate an array of solar panels 12. One system in one of the rows 56 is connected to an adjacent system 10 in a neighboring row 56 by one or more of the runner elements 58 (e.g. metal bar stock, tube stock, etc.). Referring to FIG. 15, one example assembly configuration is where one of the support members 18 (via member element 19c) is fastened by fasteners 25 (e.g. nut and bolt combination in associate with holes 42) to adjacent bottom cover panels 32 (in the same row 56) of the respective adjacent cover assemblies 26. Interposed between the cover assemblies 26 is the runner element 58, which is connected to the adjacent cover assemblies 26 also using fasteners 25, in this case preferably the same fastener 25 used to connect the support member 18 together with the adjacent cover assemblies 26. Referring to FIG. 16, shown is a further view of the connection of system 10 to adjacent system 10 via connecting the support member 18 of the support structures 16 simultaneously with the fasteners 25 to each of the respective adjacent cover assemblies 26. It is also recognized that in the case of installing a series of rows 58 in a solar panel array, the runner element 58 can also be simultaneously connected via the same fastener 25 used to connect the system 10 to adjacent system 10 (in the same row 58). Referring to FIG. 17, shown is a cross sectional view of the example connection between adjacent systems 10.

It is also recognized that rather than sharing the support member 18 between the adjacent cover assemblies 26 as shown, a plurality of support members 18 could be positioned away from edge 68 of the cover assemblies 26 (i.e. away from the edge 68 towards the respective interiors 28 respective adjacent systems 10)—not shown—such that the runner element 58 is sandwiched directly between and connected to the adjacent cover assemblies 26. Also, FIG. 18 shows an embodiment of the fastening mechanism being a tab 47 and slot 49.

We claim:

1. A ballasted mounting system for positioning a solar panel on a mounting surface, the system comprising:
a support structure having a plurality of support members for retaining the solar panel over the mounting surface at an inclined angle to the mounting surface, the support structure having a proximal end positioned adjacent to the mounting surface and the solar panel attachable to a distal end of the support structure; and
a cover assembly comprising sheet material fastened to the support structure by a plurality of fasteners and having a first cover panel positioned between the support structure and the mounting surface and a second cover panel positioned between the proximal end and the distal end, the cover assembly cooperating with the solar panel when installed to form an interior and the cover assembly being separate from the support structure and attachable and detachable to the support structure via the plurality of fasteners.

2. The system of claim 1, wherein the support structure has a pair of support members secured to the cover assembly by a plurality of mechanical fasteners.

3. The system of claim 2, wherein one of the pair of support members is attached to the solar panel towards one end of the solar panel and the other of the pair of support members is attached towards the other end of the solar panel.

4. The system of claim 2, wherein the support structure and the cover assembly are configured in an array of solar panels, such that said one of the pair of support members attaches an adjacent pair of solar panels to one another.

5. The system of claim 1 further comprising the cover assembly having a third cover panel positioned between the proximal end and the distal end while being opposite to the second cover panel.

6. The system of claim 5, wherein the first, second and third cover panels cooperate with the solar panel to form the interior that is open-ended.

7. The system of claim 6 further comprising the cover assembly having an end cover panel for covering one of the open ends.

8. The system of claim 5, wherein a panel edge adjacent to the solar panel is spaced apart from the solar panel for facilitating entrance of air into the interior, such that the panel edge is part of the second cover panel or the third cover panel.

9. The system of claim 2, wherein at least one member of the pair of support members is shaped in a triangular configuration.

10. The system of claim 9, wherein the at least one of the pair of support members is constructed of elongate members forming each of the sides of the triangular configuration.

11. The system of claim 1, wherein the first cover panel and the second cover panel are integrally formed with one another as part of the sheet material.

12. The system of claim 1, wherein the first cover panel has at least one footing positioned between the first cover panel and the mounting surface, the at least one footing composed of resilient material suitable for distribution of the weight of the mounting system over the surface area of the footing in contact with the mounting surface.

13. The system of claim 12, wherein said surface area of the footing has a plurality of channels for facilitating water flow underneath of the at least one footing.

14. The system of claim 5, wherein the third cover panel of the cover assembly is connected to the support structure using a tab and slot connection, such that the tab and slot connection is considered one of the plurality of fasteners.

15. The system of claim 1, wherein the cover assembly is fastened to the support structure by mechanical fasteners attaching the first cover panel to the support structure.

16. The system of claim 1, wherein the second cover panel is positioned at a non-perpendicular angle with respect to the first cover panel.

17. The system of claim 4 further comprising the array of solar panels ordered in rows, such that a plurality of runner elements connect one of the rows to another of the rows of the array.

18. The system of claim 17, wherein the runners are connected to the support structure by the same fasteners connecting the cover assembly to the support structure.

19. The system of claim 5, wherein the first cover panel and the second cover panel and the third cover panel are integrally formed with one another as part of the sheet material.
